(19) United States
(12) Patent Application Publication
(10) Pub. No.: US 2023/0102035 A1
(43) Pub. Date: Mar. 30, 2023

(54) Substrate Processing Apparatus, Method of Manufacturing Semiconductor Device and Non-transitory Computer-readable Recording Medium

(71) Applicant: Kokusai Electric Corporation, Tokyo (JP)

(72) Inventors: Takuya SAITO, Toyama (JP); Akira TAKAHASHI, Toyama (JP); Hiroshi HIROTANI, Toyama (JP); Taiyo OKAZAKI, Toyama (JP)

(21) Appl. No.: 17/947,399

(22) Filed: Sep. 19, 2022

(30) Foreign Application Priority Data
Sep. 28, 2021 (JP) 2021-157508

(51) Int. Cl. H01L 21/67

(52) U.S. Cl. CPC H01L 21/67017

(57) ABSTRACT

There is provided a technique for easily adjusting the inner atmosphere of the transfer chamber as desired when forming the air flow in the transfer chamber by using different gases. According to one aspect thereof, there is provided a technique including: a transfer chamber including a transfer space; a first purge gas supplier; a second purge gas supplier; an exhauster; a circulation path connecting two ends of the transfer space; a fan provided on the circulation path or at an end portion of the circulation path to circulate the inner atmosphere of the transfer chamber; and a controller for controlling the fan such that a rotational speed of the fan varies between a first purge mode where the first purge gas is supplied through the first purge gas supplier and a second purge mode where the second purge gas is supplied through the second purge gas supplier.

### CROSS REFERENCE TO RELATED APPLICATIONS

This application claims priority under 35 U.S.C. § 119(s)-(d) to Japanese Patent Application No. 2021-157508, filed on Sep. 28, 2021, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

For example, a substrate processing apparatus used in a manufacturing process of a semiconductor device may include: a loading port structure at which a substrate is transferred (or loaded) into or transferred (or unloaded) out of a wafer cassette in which a plurality of substrates including the substrate is accommodated; and a transfer chamber in which the substrate is transferred among the loading port structure, a load lock chamber and a substrate process chamber. Further, according to some related arts, a structure (or a system) capable of circulating a clean air or an inert gas in the transfer chamber may be provided such that an air flow of the clean air or an air flow of the inert gas is formed in the transfer chamber. When circulating a gas in the transfer chamber, depending on a situation, an inner atmosphere of the transfer chamber may be adjusted to a desired atmosphere.

### SUMMARY

According to the present disclosure, there is provided a technique capable of easily adjusting an inner atmosphere of a transfer chamber to a desired atmosphere when forming an air flow in the transfer chamber by using a plurality of different gases.

According to one aspect of the technique of the present disclosure, there is provided a substrate processing apparatus including: a transfer chamber provided with a transfer space in which a substrate unloaded from a substrate storage container is transferred; a first purge gas supplier through which a first purge gas is supplied into the transfer chamber; a second purge gas supplier through which a second purge gas different from the first purge gas is supplied into the transfer chamber; an exhauster through which an inner atmosphere of the transfer chamber is exhausted; a circulation path connecting one end and the other end of the transfer space; a fan provided on the circulation path or provided at an end portion of the circulation path and capable of circulating the inner atmosphere of the transfer chamber; and a controller configured to be capable of controlling the fan such that a rotational speed of the fan varies between a first purge mode in which the first purge gas is supplied through the first purge gas supplier and a second purge mode in which the second purge gas is supplied through the second purge gas supplier.

### BRIEF DESCRIPTION OF THE DRAWINGS

FIG. 1 is a diagram schematically illustrating a configuration of a substrate processing apparatus according to one or more embodiments of the present disclosure.

FIG. 2 is a diagram schematically illustrating a vertical cross-section of the substrate processing apparatus according to the embodiments of the present disclosure.

FIG. 3 is diagram schematically illustrating a first transfer chamber and its peripheral structures of the substrate processing apparatus according to the embodiments of the present disclosure.

FIG. 4 is a block diagram schematically illustrating a configuration of a controller and related components of the substrate processing apparatus according to the embodiments of the present disclosure.

FIG. 5 is a flow chart schematically illustrating a state transition according to opening and closing of a maintenance door of the substrate processing apparatus according to the embodiments of the present disclosure.

### DETAILED DESCRIPTION

### Embodiments of the Present Disclosure

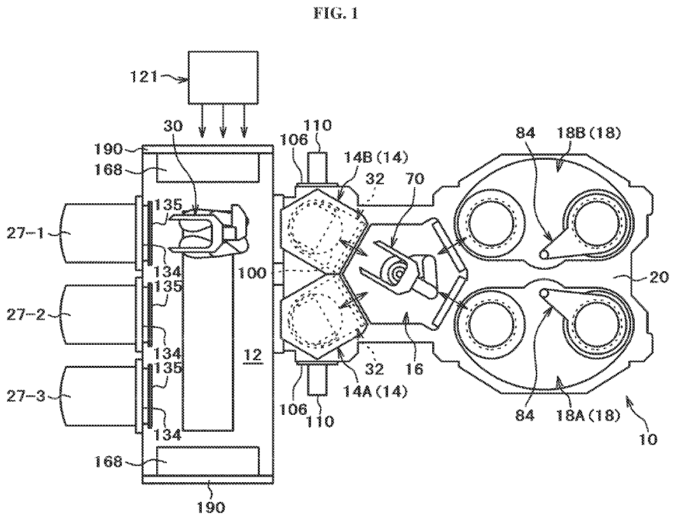

Hereinafter, one or more embodiments (also simply referred to as “embodiments”) according to the technique of the present disclosure will be described with reference to FIGS. 1 through 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

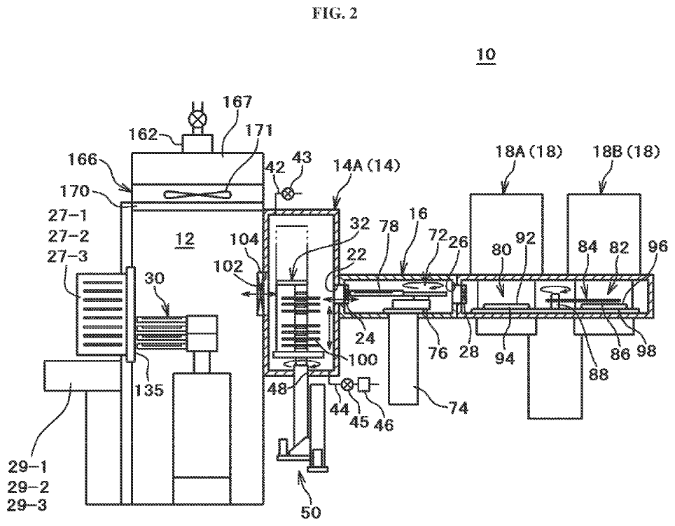

As shown in FIGS. 1 and 2, a substrate processing apparatus 10 according to the present embodiments may include: a first transfer chamber 12 serving as an atmospheric pressure side transfer chamber (which is an EFEM (Equipment Front-End Module)); loading port structures 29-1 through 29-3 connected to the first transfer chamber 12 and configured such that pods 27-1 through 27-3 serving as substrate storage containers are placed thereon; load lock chambers 14A and 14B serving as pressure-controlled preliminary chambers; a second transfer chamber 16 serving as a vacuum transfer chamber; and process chambers 18A and 18B in which a plurality of substrates including a substrate 100 are processed. Hereinafter, the plurality of substrates including the substrate 100 may also be referred to as “substrates 100”. The loading port structures 29-1 through 29-3 are provided with pod opening/closing structures capable of opening or closing lids of the pods 27-1 through 27-3, respectively, such that the substrates 100 are capable of being transferred (or loaded) into or transferred (or unloaded) out of the first transfer chamber 12 through the loading port structures 29-1 through 29-3. Further, a partition wall (which is a boundary wall) 20 is provided so as to separate the process chamber 18A and the process chamber 18B. According to the present embodiments, a semiconductor wafer such as a silicon wafer on which a semiconductor device is manufactured may be used as the substrate 100.

According to the present embodiments, configurations of the load lock chambers 14A and 14B (including configurations associated with the load lock chambers 14A and 14B) are substantially the same. Therefore, the load lock chambers 14A and 14B may also be collectively or individually referred to as a “load lock chamber 14”. Further, according to the present embodiments, configurations of the process chambers 18A and 18B (including configurations associated with the process chambers 18A and 18B) are substantially the same. Therefore, the process chambers 18A and 18B may also be collectively or individually referred to as a “process chamber 18”.

As shown in FIG. 2, a communication structure 22 is provided between the load lock chamber 14 and the second transfer chamber 16 so as to communicate between adjacent chambers (that is, the load lock chamber 14 and the second transfer chamber 16). The communication structure 22 is configured to be opened or closed by a gate valve 24.

As shown in FIG. 2, a communication structure 26 is provided between the second transfer chamber 16 and the process chamber 18 so as to communicate between adjacent chambers (that is, the second transfer chamber 16 and the process chamber 18). The communication structure 26 is configured to be opened or closed by a gate valve 28.

A first robot 30 serving as an atmospheric pressure side transfer device is provided in the first transfer chamber 12. The first robot 30 is capable of transferring the substrate 100 between the load lock chamber 14 and each of the pods 27-1 through 27-3 placed on the loading port structures 29-1 through 29-3, respectively. The first robot 30 is configured to be capable of simultaneously transferring two or more substrates among the substrates 100 in the first transfer chamber 12. Further, an inside of the first transfer chamber 12 is configured to be purged by circulating therein a purge gas described later.

The lids of the pods 27-1 through 27-3 are configured to be opened and closed by openers 135 serving as lid opening/closing structures (that is, the pod opening/closing structures described above) provided at the loading port structures 29-1 through 29-3, respectively. When the lid of each of the pods 27-1 through 27-3 are open, each of the pods 27-1 through 27-3 communicates with the inside of the first transfer chamber 12 through openings 134 provided at a housing 180 of the first transfer chamber 12.

An unprocessed substrate among the substrates 100 is transferred (or loaded) into the load lock chamber 14 by the first robot 30. Hereinafter, the unprocessed substrate among the substrates 100 may also be simply referred to as an “unprocessed substrate 100”. The unprocessed substrate 100 loaded into the load lock chamber 14 is then transferred (or unloaded) out of the load lock chamber 14 by a second robot 70 described later. On the other hand, a processed substrate among the substrates 100 is transferred into the load lock chamber 14 by the second robot 70. Hereinafter, the processed substrate among the substrates 100 may also be simply referred to as a “processed substrate 100”. The processed substrate 100 loaded into the load lock chamber 14 is then transferred out of the load lock chamber 14 by the first robot 30.

A boat 32 serving as a support capable of supporting the substrate 100 is provided in the load lock chamber 14. The boat 32 is provided so as to support the substrates 100 in a multistage manner with a predetermined interval therebetween and so as to accommodate the substrates 100 in a horizontal orientation. The boat 32 may be embodied by a structure in which an upper plate and a lower plate are connected by a plurality of support columns.

A gas supply pipe 42 communicating with an inside of the load lock chamber 14 is connected to the load lock chamber 14 such that an inert gas is capable of being supplied into the load lock chamber 14 through the gas supply pipe 42. A valve 43 may be provided at the gas supply pipe 42. Further, an exhaust pipe 44 communicating with the inside of the load lock chamber 14 is connected to the load lock chamber 14. A valve 45 and a vacuum pump 46 serving as an exhaust apparatus are provided at the exhaust pipe 44 from an upstream side toward a downstream side of the exhaust pipe 44 along a gas flow direction.

An opening 102 is provided on an outer peripheral wall of the load lock chamber 14 adjacent to the first robot 30. The first robot 30 is configured to take out the substrate 100 from the boat 32 through the opening 102 in a state where the substrate 100 is supported by the boat 32. Further, a gate valve 104 capable of opening and closing the opening 102 is provided on the outer peripheral wall of the load lock chamber 14. A driving structure 50 capable of rotating the boat 32 and elevating or lowering the boat 32 through an opening 48 is provided below the load lock chamber 14.

The second robot 70 is provided in the second transfer chamber 16. The second robot 70 is configured to transfer the substrate 100 between the load lock chamber 14 and the process chamber 18. The second robot 70 may include: a substrate transfer structure 72 capable of supporting and transferring the substrate 100; and a transfer driving structure 74 capable of rotating the substrate transfer structure 72 and elevating or lowering the substrate transfer structure 72. An arm structure 76 is provided in the substrate transfer structure 72. The arm structure 76 is provided with a finger 78 on which the substrate 100 is placed.

The substrate 100 is moved from the load lock chamber 14 to the process chamber 18 by moving the substrate 100 supported by the boat 32 into the second transfer chamber 16 by the second robot 70 and further moving the substrate 100 into the process chamber 18 by the second robot 70. Further, the substrate 100 is moved from the process chamber 18 to the load lock chamber 14 by moving the substrate 100 in the process chamber 18 into the second transfer chamber 16 by the second robot 70 and then supporting the substrate 100 on the boat 32.

A first process structure 80, a second process structure 82 and a substrate moving structure 84 capable of transferring the substrate 100 between the second process structure 82 and the second robot 70 are provided in the process chamber 18. The first process structure 80 may include a first mounting table 92 on which the substrate 100 is placed and a first heater 94 configured to heat the first mounting table 92. The second process structure 82 may include a second mounting table 96 on which the substrate 100 is placed and a second heater 98 configured to heat the second mounting table 96.

The substrate moving structure 84 is constituted by a moving structure 86 capable of supporting the substrate 100 and a moving shaft 88 provided in the vicinity of the partition wall 20. Further, by rotating the moving structure 86 toward the first process structure 80, the substrate moving structure 84 is capable of transferring the substrate 100 to or from the second robot 70 at the first process structure 80. Thereby, the substrate moving structure 84 is capable of moving the substrate 100 transferred by the second robot 70 to the second mounting table 96 of the second process structure 82 and also capable of moving the substrate 100 placed on the second mounting table 96 to the second robot 70.

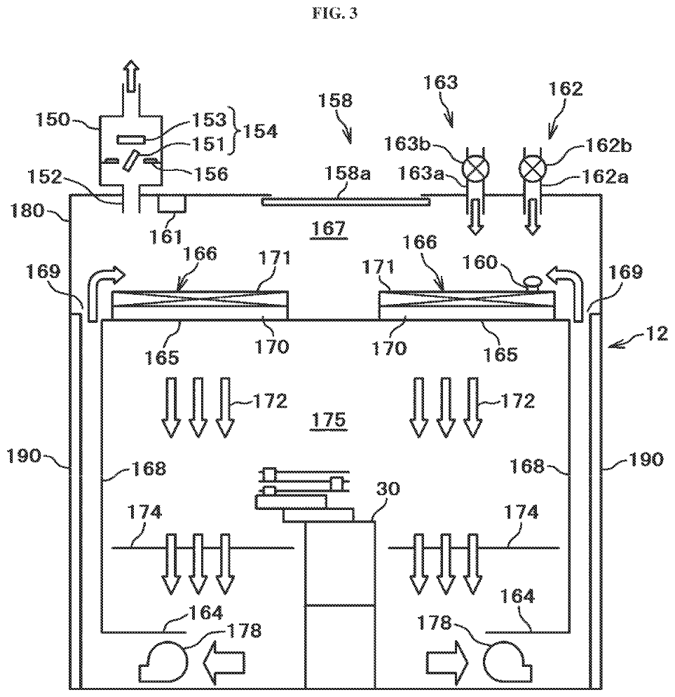

Subsequently, a configuration of the first transfer chamber 12 according to the present embodiments will be described in detail with reference to FIG. 3. In the present specification, the first transfer chamber 12 mainly refers to a structure constituted by the housing 180, configurations provided in the housing 180, gas suppliers (which is gas supply structures or gas supply systems) and an exhauster (which is an exhaust structure or an exhaust system) connected to the housing 180 and the like. However, the first transfer chamber 12 may refer to an inner space partitioned by the housing 180.

### Purge Gas Supplier

An inert gas supply structure 162 configured to supply an inert gas into the first transfer chamber 12, a dry air supply structure 163 configured to supply dry air into the first transfer chamber 12 and an air supply structure (which is an air intake structure) 158 configured to supply air into the first transfer chamber 12 are provided in the housing 180. The inert gas supply structure 162, the dry air supply structure 163 and the air supply structure 158 may be collectively referred to as a “purge gas supplier” (which is a purge gas supply structure or a purge gas supply system). That is, the purge gas supplier is constituted mainly by the inert gas supply structure 162, the dry air supply structure 163 and the air supply structure 158.

The inert gas supply structure 162 may be constituted by a supply pipe 162a connected to an inert gas supply source (not shown) and a mass flow controller (MFC) 162b serving as a flow rate controller (which is a flow rate control structure) provided on the supply pipe 162a. A valve serving as an opening/closing valve may be further provided on the supply pipe 162a at downstream of the MFC 162b. An inert gas supplier (which is an inert gas supply structure or an inert gas supply system) is constituted mainly by the inert gas supply structure 162. The inert gas supplier may further include the inert gas supply source.

For example, nitrogen (N2) gas or a rare gas such as argon (Ar) gas, helium (He) gas, neon (Ne) gas and xenon (Xe) gas may be used as the inert gas. For example, one or more of the gases described above may also be used as the inert gas. The same also applies to other inert gases described later.

The dry air supply structure 163 may be constituted by a supply pipe 163a connected to a dry air supply source (not shown) and a mass flow controller (MFC) 163b provided on the supply pipe 163a. A valve serving as an opening/closing valve may be further provided on the supply pipe 163a at downstream of the MFC 163b. A dry air supplier (which is a dry air supply structure or a dry air supply system) is constituted mainly by the dry air supply structure 163. The dry air supplier may further include the dry air supply source.

The dry air refers to a gas whose moisture concentration is lower than that of the air. The dry air may be obtained by removing the moisture from the normal air (atmosphere). It is preferable that the moisture concentration of the dry air is, for example, equal to or lower than 1,000 ppm, and preferably equal to or lower than 100 ppm. Further, it is preferable that compositions of the dry air are substantially the same as the normal air except for the moisture. Further, in the present specification, the “air” or “normal air” to be compared with the dry air in terms of the moisture concentration mainly refers to the air introduced (or taken in) through the air supply structure 158. However, the “air” or “normal air” is not limited thereto.

Further, the dry air supply source may include a moisture removing structure (which is a moisture removing apparatus), and a gas obtained by removing the moisture from the air (which is taken into the moisture removing structure) by the moisture removing structure may be supplied to the supply pipe 163a as the dry air. Further, the dry air supply source may be embodied by a cylinder, an ampoule or the like in which the dry air is stored.

The air supply structure 158 is constituted by an intake damper 158a provided in an opening of the housing 180 communicating with the atmosphere. An air supplier (which is an air supply structure or an air supply system) is constituted mainly by the air supply structure 158.

Further, each of the inert gas and the dry air is a gas whose moisture concentration is lower than that of the air. Thus, hereinafter, the inert gas and the dry air may also be collectively referred to as a “dry gas”.

### Exhauster

An exhaust path 152 and a pressure control structure 150, which constitute the exhauster (which is the exhaust structure or the exhaust system) configured to exhaust the gas in the first transfer chamber 12 (that is, an inner atmosphere of the first transfer chamber 12), are provided in the housing 180. The pressure control structure 150 is configured to be capable of controlling an inner pressure of the first transfer chamber 12 to an appropriate pressure by controlling opening and closing operations of an adjusting damper 154 and an exhaust damper 156. The pressure control structure 150 may be constituted by the adjusting damper 154 configured to maintain the inner pressure of the first transfer chamber 12 at a predetermined pressure and the exhaust damper 156 configured to fully open or fully close the exhaust path 152. With such a configuration, it is possible to control the inner pressure of the first transfer chamber 12. The adjusting damper 154 may be constituted by an automatic damper (or a back pressure valve) 151 configured to be opened when the inner pressure of the first transfer chamber 12 is higher than the predetermined pressure and a press damper 153 configured to control an opening and closing operation of the automatic damper 151. The exhaust path 152 on a downstream side of the pressure control structure 150 is connected to the exhaust apparatus such as a blower and an exhaust pump. For example, the exhaust apparatus may be a part of a facility in which the substrate processing apparatus 10 is installed, or the exhaust apparatus may constitute the substrate processing apparatus 10. Further, the exhaust apparatus may be regarded as a part of the exhauster (which is the exhaust structure or the exhaust system). That is, the exhauster may further include the exhaust apparatus.

### Gas Circulation Structure

In the first transfer chamber 12 are provided a transfer space 175 serving as a space in which the substrate 100 is transferred, an opening 164 serving as a suction port provided at an end (first end) of the transfer space 175, an opening 165 serving as a delivery port provided at the other end (second end) of the transfer space 175, a circulation duct 168 and an upper space (which is a buffer space or a buffer structure) 167 constituting a circulation path connecting the openings 164 and 165, and a fan 171 provided on or at an end portion of the circulation path and capable of circulating the gas in the first transfer chamber 12 (in particular, the gas in the circulation path and the transfer space 175) (that is, the inner atmosphere of the first transfer chamber 12) in a direction from the delivery port toward the suction port. With such a configuration, the purge gas introduced into the first transfer chamber 12 circulates within the first transfer chamber 12 including the transfer space 175.

### Transfer Space

The first robot 30 is installed in the transfer space 175. The transfer space 175 is configured to communicate with the pods 27-1 through 27-3 and the load lock chamber 14 through the openings 134 and the opening 102, respectively. A perforated plate 174 serving as a gas guide plate configured to adjust a flow of the purge gas is provided directly below a horizontal movement arm (not shown) of the first robot 30. The perforated plate 174 is provided with a plurality of holes. For example, the perforated plate 174 is configured as a punched panel. The transfer space 175 is divided into a first space (which is a space above the perforated plate 174) and a second space (which is a space below the perforated plate 174) with the perforated plate 174 interposed therebetween.

### Circulation Path

Two openings including the opening 164 through which the purge gas flowed in the transfer space 175 is sucked and circulated are provided in a lower portion of the transfer space 175 (for example, in the vicinity of a bottom of the transfer space 175) respectively on a left and right sides of the first robot 30. Hereinafter, the two openings including the opening 164 may also be referred to as “openings 164”. Further, two openings including the opening 165 through which the purge gas is ejected (or sent) and circulated are provided in an upper portion of the transfer space 175 (for example, in the vicinity of a ceiling of the transfer space 175) respectively on the left and right sides of the first robot 30. Hereinafter, the openings including the opening 165 may also be referred to as “openings 165”.

The upper space 167 serving as the buffer space (or the buffer structure) to which the purge gas supplier and the exhauster are connected is provided above the transfer space 175 through the openings 165.

The upper space 167 and the openings 164 provided in the lower portion of the transfer space 175 are connected by circulation ducts including the circulation duct 168. Hereinafter, the circulation ducts including the circulation duct 168 may also be referred to as “circulation ducts 168”. For example, the circulation ducts 168 are respectively disposed on the left and right sides of the first robot 30.

The circulation path is constituted by the upper space 167 and the circulation ducts 168. That is, the purge gas supplied into the first transfer chamber 12 circulates around through the transfer space 175 and the circulation path constituted by the circulation ducts 168 and the upper space 167.

### Clean Air Supplier

Fans including the fan 171 serving as a first fan (which is a blower) capable of ejecting the purge gas in the upper space 167 (that is, an inner atmosphere of the upper space 167) into the transfer space 175 are provided at the openings 165 in the ceiling of the transfer space 175, respectively. Hereinafter, the fans including the fan 171 may also be referred to as “fans 171”. In other words, the fans 171 are provided on or at end portions of the circulation path. Filter structures including a filter structure 170 is provided on bottom surfaces of the fans 171, respectively. Hereinafter, the filter structures including the filter structure 170 may also be referred to as “filter structures 170”. Each of the filter structures 170 serves as a filter capable of removing a dust and impurities in the purge gas ejected (or sent) through the fans 171. A clean air supplier (which is a clean air supply structure or a clean air supply system) 166 is constituted by the fans 171 and the filter structures 170. Each of the filter structures 170 may include a moisture removing filter capable of collecting and removing the moisture in the gas passing through each of the filter structures 170. For example, the moisture removing filter may be constituted by a chemical filter capable of adsorbing the moisture.

Hereinafter, the flow of the purge gas in the first transfer chamber 12 will be described. First, the purge gas whose flow rate is controlled is introduced (or supplied) into the upper space 167 from the purge gas supplier. The purge gas in the upper space 167 is ejected (or sent) through the ceiling of the transfer space 175 into the transfer space 175 by the clean air supplier 166 (more specifically, by the fans 171). Thereby, a downward flow of the purge gas in the transfer space 175 in a direction from the openings 165 to the openings 164 is formed. The purge gas flowed downward in the transfer space 175 is returned to the upper space 167 through the openings 164 and the circulation ducts 168. Thereby, a flow path through which the purge gas is circulated in the first transfer chamber 12 is formed.

The fan 171 is configured to be capable of being adjusted to obtain a desired rotational speed (which is the number of rotations) between 100% (which is the maximum rotational speed of the fan 171) and 0% (which is a state in which the rotation of the fan 171 is stopped) in accordance with an instruction from a controller 121 described later. For example, the fan 171 may be configured to be steplessly controlled via a PLC (Programmable Logic Controller).

When a conductance of each of the circulation ducts 168 is small, fans including a fan 178 serving as a second fan (which is a blower) capable of promoting a circulation of the purge gas may be further provided at the openings 164 (which are respectively disposed on the left and right sides of the first robot 30), respectively. Hereinafter, the fans including the fan 178 may also be referred to as “fans 178”. When the fans 178 are further provided, from a viewpoint of ease of control, it is preferable to control the fans 171 and the fans 178 such that a rotational speed of each of the fans 178 is maintained constant and a rotational speed of each of the fans 171 is variably controlled as described later. However, the present embodiments are not limited thereto. For example, both of the rotational speed of each of the fans 171 and the rotational speed of each of the fans 178 may be variably controlled.

### Maintenance Door

Maintenance doors including a maintenance door 190 serving as a door (which is an opening/closing structure) are provided on both sides of the first transfer chamber 12 interposed between the first robot 30 and the loading port structures 29-1 through 29-3. Hereinafter, the maintenance doors including the maintenance door 190 may also be referred to as “maintenance doors 190”. The maintenance doors 190 are configured to close maintenance openings serving as openings used for performing a maintenance operation of the inside of the first transfer chamber 12, respectively. Each of the maintenance doors 190 is attached to a side surface of the first transfer chamber 12, wherein one edge of the first transfer chamber 12 extending in a vertical direction and located close to a front side of the substrate processing apparatus 10 is used as a rotation axis of each of the maintenance doors 190. An operating personnel who performs the maintenance operation of the substrate processing apparatus 10 may access the inside of the first transfer chamber 12 through the maintenance doors 190 and may perform the maintenance operation of the inside of the first transfer chamber 12.

### Oxygen Concentration Sensor

An oxygen concentration detector 160 serving as an oxygen concentration sensor capable of detecting an oxygen concentration in the first transfer chamber 12 is provided inside the first transfer chamber 12. According to the present embodiments, the oxygen concentration detector 160 is arranged in the upper space 167 and directly below the purge gas supplier. However, the oxygen concentration detector 160 may be provided in a location such as the transfer space 175, the circulation duct 168 and the exhaust path 152. In addition, a plurality of oxygen concentration detectors including the oxygen concentration detector 160 may be provided. Hereinafter, the plurality of oxygen concentration detectors including the oxygen concentration detector 160 may also be referred to as “oxygen concentration detectors 160”. For example, by providing the oxygen concentration detectors 160 at different positions in the transfer space 175, it is possible to detect an oxygen concentration deviation in the transfer space 175. When the oxygen concentration deviation in the transfer space 175 is detected, as will be described later, it is possible to control the rotational speed of each of the fans 171 to increase so as to reduce the oxygen concentration deviation.

### Moisture Concentration Sensor

A moisture concentration detector 161 serving as a moisture concentration sensor capable of detecting a moisture concentration in the first transfer chamber 12 is provided inside the first transfer chamber 12. According to the present embodiments, the moisture concentration detector 161 is arranged in the upper space 167 and in the vicinity of the exhaust path 152. However, the moisture concentration detector 161 may be provided in a location such as the transfer space 175 and the circulation duct 168. In addition, a plurality of moisture concentration detectors including the moisture concentration detector 161 may be provided. Hereinafter, the plurality of moisture concentration detectors including the moisture concentration detector 161 may also be referred to as “moisture concentration detectors 161”. For example, by providing the moisture concentration detectors 161 at different positions in the transfer space 175, it is possible to detect a moisture concentration deviation in the transfer space 175. When the moisture concentration deviation in the transfer space 175 is detected, as will be described later, it is possible to control the rotational speed of each of the fans 171 to increase so as to reduce the moisture concentration deviation. The moisture concentration detector 161 may be configured as a moisture concentration detecting structure capable of detecting the moisture concentration (which is an absolute humidity). However, the moisture concentration detector 161 may be configured as a structure such as a dew point meter capable of measuring a dew point temperature and a relative hygrometer capable of measuring a relative humidity. That is, as an index indicating the moisture concentration acquired by using the moisture concentration detector 161, at least one of the absolute humidity, the relative humidity or the dew point temperature may be used.

### Controller

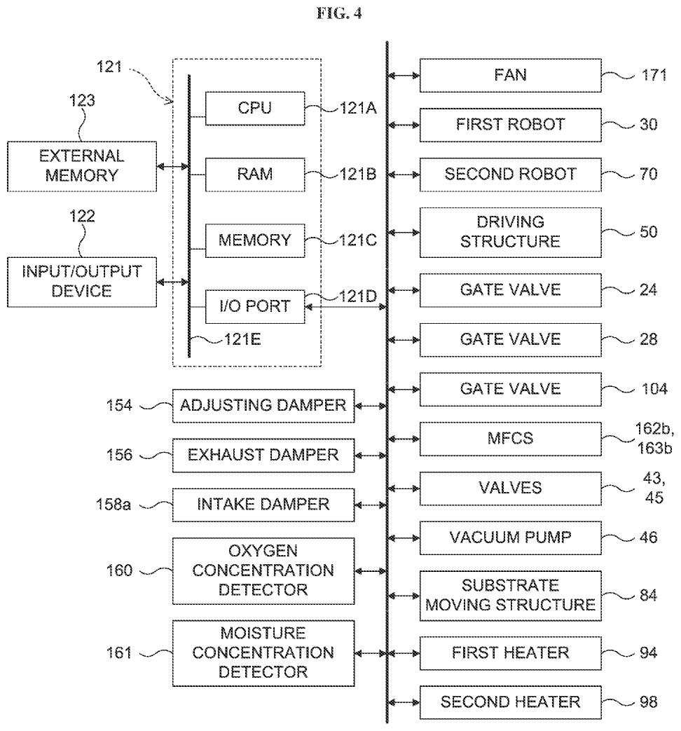

The substrate processing apparatus 10 includes the controller 121 serving as a control structure as shown in FIG. 4. For example, the controller 121 is constituted by a computer including a CPU (Central Processing Unit) 121A, a RAM (Random Access Memory) 121B, a memory 121C and an I/O port (input/output port) 121D.

The RAM 121B, the memory 121C and the I/O port 121D may exchange data with the CPU 121A through an internal bus 121E. For example, an input/output device 122 constituted by components such as a touch panel may be connected to the controller 121.

For example, the memory 121C is configured by a component such as a flash memory and a hard disk drive (HDD). For example, a control program configured to control operations of the substrate processing apparatus 10 or a process recipe containing information on sequences and conditions of a substrate processing described later is readably stored in the memory 121C. The process recipe is obtained by combining steps of the substrate processing described later such that the controller 121 constituted by the computer can execute the steps by using the substrate processing apparatus 10 to acquire a predetermined result, and functions as a program. Hereinafter, the process recipe and the control program may be collectively or individually referred to as a “program”. Further, the process recipe may also be simply referred to as a “recipe”. Thus, in the present specification, the term “program” may refer to the recipe alone, may refer to the control program alone, or may refer to both of the recipe and the control program. The RAM 121B functions as a memory area (work area) where a program or data read by the CPU 121A is temporarily stored.

The I/O port 121D is electrically connected to the components described above such as the fan 171, the first robot 30, the second robot 70, the driving structure 50, the gate valve 24, the gate valve 28, the gate valve 104, the valves 43 and 45, the vacuum pump 46, the substrate moving structure 84, the first heater 94 and the second heater 98.

The CPU 121A is configured to read and execute the control program stored in the memory 121C, and to read the recipe stored in the memory 121C in accordance with an instruction such as an operation command inputted via the input/output device 122. For example, in accordance with contents of the read recipe, the CPU 121A is configured to be capable of controlling various operations such as a transfer operation of the substrates 100 by the first robot 30, the second robot 70, the driving structure 50 and the substrate moving structure 84, a flow rate adjusting operation of the purge gas by the MFCs 162b and 163b and the intake damper 158a, opening and closing operations of the adjusting damper 154 and the exhaust damper 156, an air blow volume adjusting operation by the fan 171, opening and closing operations of the openers 135, the gate valve 24, the gate valve 28 and the gate valve 104, a flow rate and a pressure regulating operation by the valve 45 and the vacuum pump 46, and a temperature adjusting operation by the first heater 94 and the second heater 98.

The controller 121 may be embodied by installing the above-described program stored in an external memory 123 into the computer. For example, the external memory 123 may be constituted by a component such as a magnetic disk such as a hard disk, an optical disk such as a CD, a magneto-optical disk such as an MO and a semiconductor memory such as a USB memory. The memory 121C and the external memory 123 may be embodied by a non-transitory computer readable recording medium. Hereafter, the memory 121C and the external memory 123 may be collectively or individually referred to as a “recording medium”. In the present specification, the term “recording medium” may refer to the memory 121C alone, may refer to the external memory 123 alone, and may refer to both of the memory 121C and the external memory 123. Instead of the external memory 123, a communication interface such as the Internet and a dedicated line may be used for providing the program to the computer.

### (2) Substrate Processing

Subsequently, a method of manufacturing a semiconductor device by using the substrate processing apparatus 10, that is, the steps (or the sequences) (that is, the substrate processing) of processing the substrate 100 will be described. In the following description, as described above, the operations of the components constituting the substrate processing apparatus 10 are controlled by the controller 121.

First, the lids of the pods 27-1 through 27-3 are opened by the openers 135. Thereafter, the substrates 100 stored in the pods 27-1 through 27-3 are transferred into the first transfer chamber 12 by the first robot 30.

When transferring the substrates 100 into the first transfer chamber 12, the purge gas supplied through the purge gas supplier is introduced into the first transfer chamber 12. By circulating the purge gas in the first transfer chamber 12 by the fans 171, the inside of the first transfer chamber 12 is purged. According to the present embodiments, depending on a state of the substrate 100 being transferred and contents of the substrate processing performed in the process chamber 18, the inner atmosphere of the first transfer chamber 12 (in particular, an inner atmosphere of the transfer space 175) formed by circulating the purge gas may be different. That is, a desired oxygen concentration, a desired moisture concentration and a desired type of the gas for forming the inner atmosphere of the first transfer chamber 12 may be different. According to the present embodiments, as will be described later, by supplying at least one of the inert gas, the dry air or the air as the purge gas into the first transfer chamber 12, it is possible to maintain the inner atmosphere of the first transfer chamber 12 to a desired atmosphere.

Subsequently, the inert gas is supplied into the load lock chamber 14 through the gas supply pipe 42. Thereby, it is possible to set an inner pressure of the load lock chamber 14 to an atmospheric pressure. After setting the inner pressure of the load lock chamber 14 to the atmospheric pressure, the gate valve 104 is opened.

Subsequently, the substrate 100 loaded into the first transfer chamber 12 is transferred into the load lock chamber 14 by the first robot 30, and is placed on the boat 32.

After a predetermined number of the substrates 100 are supported by the boat 32, the gate valve 104 is closed and the valve 45 of the exhaust pipe 44 is opened so as to exhaust the inside of the load lock chamber 14 by the vacuum pump 46. Thereby, it is possible to set the inner pressure of the load lock chamber 14 to a vacuum pressure (vacuum level). Further, when setting the inner pressure of the load lock chamber 14 to the vacuum pressure, an inner pressure of the second transfer chamber 16 and an inner pressure of the process chamber 18 are also set to the vacuum pressure.

Subsequently, the substrate 100 is transferred from the load lock chamber 14 to the process chamber 18. Specifically, first, the gate valve 24 is opened. When opening the gate valve 24, the driving structure 50 elevates and lowers the boat 32 such that the substrate 100 supported by the boat 32 is capable of being transferred (or taken out) by the second robot 70. Further, the driving structure 50 rotates the boat 32 such that a substrate loading/unloading port of the boat 32 faces the second transfer chamber 16.

The second robot 70 places the substrate 100 on the finger 78 of the arm structure 76 and transfers (or loads) the substrate 100 into the process chamber 18. In the process chamber 18, the substrate 100 placed on the finger 78 may be placed on the first mounting table 92 of the first process structure 80, or may be transferred to the moving structure 86 standing by on a side of the first process structure 80. After receiving the substrate 100, the moving structure 86 is rotated toward the second process structure 82 and places the substrate 100 on the second mounting table 96.

Then, in the process chamber 18, the substrate 100 is subjected to a predetermined process such as an ashing process. In the predetermined process, a temperature of the substrate 100 is elevated by being heated by a heater such as the first heater 94 and the second heater 98, or by being heated by a reaction heat generated by performing the predetermined process.

Subsequently, the substrate 100 after the predetermined process is performed (that is, the processed substrate 100) is transferred from the process chamber 18 to the load lock chamber 14. A transfer of the substrate 100 from the process chamber 18 to the load lock chamber 14 is performed in an order reverse to that of loading the substrate 100 into the process chamber 18 described above. When transferring the substrate 100 from the process chamber 18 to the load lock chamber 14, the inside of load lock chamber 14 is maintained in a vacuum state (that is, the inner pressure of the load lock chamber 14 is set to the vacuum pressure).

After the processed substrate 100 is loaded into the load lock chamber 14 and supported by the boat 32, the gate valve 24 is closed and the inert gas is supplied into the load lock chamber 14 through the gas supply pipe 42. Thereby, the inner pressure of the load lock chamber 14 is set to the atmospheric pressure.

Subsequently, the controller 121 controls the driving structure 50 to rotate the boat 32 such that the substrate loading/unloading port of the boat 32 faces the first transfer chamber 12. Then, the gate valve 104 is opened. Then, the substrate 100 is transferred to the first transfer chamber 12 by using the first robot 30.

Subsequently, the lids of the pods 27-1 through 27-3 are opened by the openers 135, respectively. Thereafter, the first robot 30 transfers the substrates 100 (which are transferred out of the load lock chamber 14 and transferred in the first transfer chamber 12) into the pods 27-1 through 27-3. Thereby, the transfer operation of the substrates 100 is completed.

### (3) Purge Control in First Transfer Chamber

The substrate processing apparatus 10 according to the present embodiments is operated based on a plurality of purge modes (purge states) such that a purge state (such as a supply flow rate (speed), an exhaust flow rate (speed) and a circulation flow rate (speed) of the purge gas) and the inner atmosphere of the first transfer chamber 12 (in particular, the inner atmosphere of the transfer space 175) are different for each of the purge modes, and is configured to switch between the plurality of purge modes in accordance with the circumstances of the substrate processing apparatus 10.

The plurality of purge modes can be switched, for example, before the substrates 100 stored in the pods 27-1 through 27-3 are transferred into the first transfer chamber 12, or after the substrates 100 are transferred (or unloaded) from the inside of the first transfer chamber 12 to the pods 27-1 through to 27-3 and then stored in the pods 27-1 through to 27-3.

Further, the plurality of purge modes can be switched, for example, in accordance with an instruction inputted from the input/output device 122 or the program, by changing information (or a flag) in a memory space secured in the RAM 121B or the like constituting the controller 121. In the memory space is stored the information indicating that the substrate processing apparatus 10 is in a certain purge mode among the plurality of purge mode. Based on the information in the memory space, the controller 121 instructs the substrate processing apparatus 10 to perform each purge mode.

Hereinafter, examples of the plurality of purge modes will be described.

### Purge Mode A: Inert Gas Purge Mode

In an inert gas purge mode, the inert gas is supplied through the inert gas supply structure 162 into the first transfer chamber 12 to purge an inside of the transfer space 175 with the inert gas. Specifically, the MFC 162b is opened to supply the inert gas into the upper space 167 and the fan 171 is operated (or rotated) to circulate the inert gas within the first transfer chamber 12. Further, simultaneously, an opening/closing state and an opening degree of each of the adjusting damper 154 and the exhaust damper 156 of the pressure control structure 150 are adjusted so as to exhaust the inner atmosphere of the first transfer chamber 12 (which is the gas in the first transfer chamber 12). As a result, the inside of the first transfer chamber 12 is purged with the inert gas, and the inner atmosphere of the first transfer chamber 12 before the present purge mode is replaced with the inert gas introduced into the first transfer chamber 12.

According to the present embodiments, for example, when the inside of the first transfer chamber 12 is purged with the air before the present purge mode, by purging the inside of the first transfer chamber 12 with the inert gas in the present purge mode, it is possible to lower the oxygen concentration and the moisture concentration in the first transfer chamber 12. Similarly, for example, when the inside of the first transfer chamber 12 is purged with the dry air before the present purge mode, by purging the inside of the first transfer chamber 12 with the inert gas in the present purge mode, it is possible to lower the oxygen concentration in the first transfer chamber 12.

Further, oxygen and the moisture present in the transfer space 175 may react with a surface of the substrate 100 to cause an oxidation reaction. However, such an oxidation reaction may not be desirable. In the present purge mode, by reducing the oxygen concentration and the moisture concentration in the transfer space 175, it is possible to suppress an occurrence of the oxidation reaction which is not desirable.

### Purge Mode B: Dry Air Purge Mode

In a dry air purge mode, the dry air is supplied through the dry air supply structure 163 into the first transfer chamber 12 to purge the inside of the transfer space 175 with the dry air. Specifically, the MFC 163b is opened to supply the dry air into the upper space 167 and the fan 171 is operated (or rotated) to circulate the dry air within the first transfer chamber 12. Further, simultaneously, similar to the inert gas purge mode, the inner atmosphere of the first transfer chamber 12 (which is the gas in the first transfer chamber 12) is exhausted. As a result, the inside of the first transfer chamber 12 is purged with the dry air, and the inner atmosphere of the first transfer chamber 12 before the present purge mode is replaced with the dry air introduced into the first transfer chamber 12.

According to the present embodiments, for example, when the inside of the first transfer chamber 12 is purged with the air before the present purge mode, by purging the inside of the first transfer chamber 12 with the dry air in the present purge mode, it is possible to lower the moisture concentration in the first transfer chamber 12.

Further, when the moisture concentration in the dry air is sufficiently low, an efficiency (or an ability) of the dry air in removing the moisture present in the first transfer chamber 12 may be higher than that of the inert gas. In such a case, it is preferable to apply the dry air purge mode in preference to the inert gas purge mode in order to remove the moisture in the first transfer chamber 12.

### Purge Mode C: Air Purge Mode

In an air purge mode (which may be referred to as “normal air purge mode” as well), the air is supplied through the air supply structure 158 into the first transfer chamber 12 to purge the inside of the transfer space 175 with the air. Specifically, the intake damper 158a is opened to supply the air into the upper space 167 and the fan 171 is operated (or rotated) to circulate the air within the first transfer chamber 12. Further, simultaneously, similar to the inert gas purge mode, the inner atmosphere of the first transfer chamber 12 (which is the gas in the first transfer chamber 12) is exhausted. As a result, the inside of the first transfer chamber 12 is purged with the air, and the inner atmosphere of the first transfer chamber 12 before the present purge mode is replaced with the air introduced into the first transfer chamber 12.

According to the present embodiments, when the inside of the first transfer chamber 12 is purged with the air, the impurities such as particles generated in the transfer space 175 and an out gas generated from the substrate 100 or the like are removed from the transfer space 175 by circulating the air therein. In addition, according to the present purge mode, the impurities are collected by the filter structure 170 and/or are discharged through the exhaust path 152. When the oxygen concentration and the moisture concentration in the transfer space 175 are equal to or less than respective allowable values without using the inert gas or the dry air, it may be preferable to apply the present purge mode from a viewpoint of cost and the like.

Further, hereinafter, the inert gas purge mode and the dry air purge mode may be collectively or individually referred to as a “dry gas purge mode”.

### Control of Rotational Speed of Fan

When the plurality of purge modes described above are performed according to the present embodiments, the fan 171 is controlled such that the rotational speed (the number of rotations) thereof may vary depending on the purge mode of the substrate processing apparatus 10.

According to the present embodiments, the rotational speed of the fan 171 in the dry air purge mode is higher than the rotational speed of the fan 171 in the air purge mode. Similarly, the rotational speed of the fan 171 in the inert gas purge mode is higher than the rotational speed of the fan 171 in the air purge mode. When the maximum rotational speed of the fan 171 is defined as 100%, the rotational speed of the fan 171 is set to be, for example, equal to or higher than 30% and less than 60% in the air purge mode and equal to or higher than 60% and less than 90% in the dry air purge mode or the inert gas purge mode.

By setting the rotational speed of the fan 171 in the dry air purge mode to be higher than that of the fan 171 in the air purge mode, it is possible to reduce the moisture concentration more quickly and uniformly in the first transfer chamber 12. That is, it is possible to suppress a local increase in the moisture concentration in the first transfer chamber 12, and it is also possible to stably maintain the moisture concentration at a low value in an entirety of the first transfer chamber 12.

Further, similarly, by setting the rotational speed of the fan 171 in the inert gas purge mode to be higher than that of the fan 171 in the air purge mode, it is possible to reduce at least one of the oxygen concentration or the moisture concentration more quickly and uniformly in the first transfer chamber 12. That is, it is possible to suppress a local increase in at least one of the oxygen concentration or the moisture concentration in the first transfer chamber 12, and it is also possible to stably maintain at least one of the oxygen concentration or the moisture concentration at low values in the entirety of the first transfer chamber 12.

For example, when the air is referred to as a “first purge gas” and the dry air is referred to as a “second purge gas”, the air supplier may also be referred to as a “first purge gas supplier” (which is a first purge gas supply structure or a first purge gas supply system), and the dry air supplier may also be referred to as a “second purge gas supplier” (which is a second purge gas supply structure or a second purge gas supply system). Further, the air purge mode may also be referred to as a “first purge mode”, and the dry air purge mode may also be referred to as a “second purge mode”. Similarly, when the air is referred to as the “first purge gas” and the inert gas is referred to as the “second purge gas”, the air supplier may also be referred to as the “first purge gas supplier”, and the inert gas supplier may also be referred to as the “second purge gas supplier”. Further, the air purge mode may also be referred to as the “first purge mode”, and the inert gas purge mode may also be referred to as the “second purge mode”.

### Control Using Oxygen Concentration Sensor

In the inert gas purge mode, a flow rate of the inert gas supplied through the inert gas supplier into the first transfer chamber 12 is controlled based on a value (which is an oxygen concentration value) detected by the oxygen concentration detector 160 serving as the oxygen concentration sensor. More specifically, an opening degree of the MFC 162b is controlled such that the oxygen concentration value detected by the oxygen concentration detector 160 is equal to or less than a predetermined value (for example, an oxygen concentration value allowed for the substrate 100 transferred in the first transfer chamber 12). For example, the opening degree of the MFC 162b with respect to the oxygen concentration value detected by the oxygen concentration detector 160 is set such that the flow rate of the inert gas when the oxygen concentration value detected by the oxygen concentration detector 160 is greater than the predetermined value is higher than the flow rate of the inert gas when the oxygen concentration value detected by the oxygen concentration detector 160 is equal to or less than the predetermined value.

By controlling the flow rate of the inert gas supplied into the first transfer chamber 12 based on the oxygen concentration value detected by the oxygen concentration detector 160, it is possible to adjust the oxygen concentration in the first transfer chamber 12 to a desired value.

Further, in the inert gas purge mode, the rotational speed of the fan 171 is controlled in accordance with the flow rate of the inert gas supplied through the inert gas supplier or in accordance with a change of the flow rate of the inert gas supplied through the inert gas supplier. Specifically, for example, when the flow rate of the inert gas (that is, the opening degree of the MFC 162b) changes to increase, the fan 171 is controlled such that the rotational speed of the fan 171 is increased in accordance with an increased amount of the flow rate of the inert gas or such that the rotational speed of the fan 171 is increased for a predetermined time.

By controlling the rotational speed of the fan 171 as described above, when the flow rate of the inert gas is changed (in particular, when the flow rate of the inert gas is changed to increase), it is possible to circulate the inner atmosphere of the first transfer chamber 12 such that an oxygen concentration distribution in the transfer space 175 is more uniformized (that is, the oxygen concentration in the transfer space 175 decreases uniformly).

Further, the rotational speed of the fan 171 may be controlled based on the oxygen concentration value detected by the oxygen concentration detector 160. Specifically, for example, the rotational speed of the fan 171 with respect to the oxygen concentration value detected by the oxygen concentration detector 160 is set such that the rotational speed of the fan 171 when the oxygen concentration value detected by the oxygen concentration detector 160 is greater than the predetermined value is higher than the rotational speed of the fan 171 when the oxygen concentration value detected by the oxygen concentration detector 160 is equal to or less than the predetermined value. By controlling the rotational speed of the fan 171 based on the oxygen concentration value detected by the oxygen concentration detector 160 as described above, it is possible to obtain substantially the same effect as the control based on the flow rate of the inert gas.

### Control Using Moisture Concentration Sensor

In at least one of the dry air purge mode or the inert gas purge mode (as described above, the dry air purge mode and the inert gas purge mode may also be collectively or individually referred to as the dry gas purge mode), a flow rate of the dry air or the flow rate of the inert gas (as described above, the dry air and the inert gas may also be collectively or individually referred to as the dry gas) supplied into the first transfer chamber 12 through the dry air supplier or the inert gas supplier (hereinafter, the dry air supplier and the inert gas supplier may also be collectively or individually referred to as a “dry gas supplier” (which is a dry gas supply structure or a dry gas supply system)) is controlled based on a value (which is a moisture concentration value) detected by the moisture concentration detector 161 serving as the moisture concentration sensor.

More specifically, in the dry air purge mode, an opening degree of the MFC 163b is controlled such that the moisture concentration value detected by the moisture concentration detector 161 is equal to or less than a predetermined value (for example, a moisture concentration value allowed for the substrate 100 transferred in the first transfer chamber 12). For example, the opening degree of the MFC 163b with respect to the moisture concentration value detected by the moisture concentration detector 161 is set such that the flow rate of the dry air when the moisture concentration value detected by the moisture concentration detector 161 is greater than the predetermined value is higher than the flow rate of the dry air when the moisture concentration value detected by the moisture concentration detector 161 is equal to or less than the predetermined value. In the inert gas purge mode, the opening degree of the MFC 162b is similarly controlled.

By controlling the flow rate of the dry gas (that is, the dry air or the inert gas) supplied into the first transfer chamber 12 based on the moisture concentration value detected by the moisture concentration detector 161, it is possible to adjust the moisture concentration in the first transfer chamber 12 to a desired value.

Further, in the dry gas purge mode, the rotational speed of the fan 171 is controlled in accordance with a flow rate of the dry gas (purge gas) supplied through the dry gas supplier or in accordance with a change of the flow rate of the dry gas (purge gas) supplied through the dry gas supplier. Specifically, for example, when the flow rate of the dry gas (that is, the opening degree of the MFC 162b or the opening degree of the MFC 163b) changes to increase, the fan 171 is controlled such that the rotational speed of the fan 171 is increased in accordance with an increased amount of the flow rate of the dry gas or such that the rotational speed of the fan 171 is increased for a predetermined time.

By controlling the rotational speed of the fan 171 as described above, when the flow rate of the dry gas is changed (in particular, when the flow rate of the dry gas is changed to increase), it is possible to circulate the inner atmosphere of the first transfer chamber 12 such that a moisture concentration distribution in the transfer space 175 is more uniformized (that is, the moisture concentration in the transfer space 175 decreases uniformly).

Further, the rotational speed of the fan 171 may be controlled based on the moisture concentration value detected by the moisture concentration detector 161. Specifically, for example, the rotational speed of the fan 171 with respect to the moisture concentration value detected by the moisture concentration detector 161 is set such that the rotational speed of the fan 171 when the moisture concentration value detected by the moisture concentration detector 161 is greater than the predetermined value is higher than the rotational speed of the fan 171 when the moisture concentration value detected by the moisture concentration detector 161 is equal to or less than the predetermined value. By controlling the rotational speed of the fan 171 based on the moisture concentration value detected by the moisture concentration detector 161 as described above, it is possible to obtain substantially the same effect as the control based on the flow rate of the dry gas.

Further, in the dry air purge mode, based on a value including the oxygen concentration value detected by the oxygen concentration detector 160 in addition to the moisture concentration value detected by the moisture concentration detector 161, a control may be performed to switch a state from the dry air purge mode to the inert gas purge mode. Specifically, in the dry air purge mode, when the oxygen concentration value detected by the oxygen concentration detector 160 exceeds the predetermined value, the inert gas is supplied into the first transfer chamber 12 by switching to the inert gas purge mode. Further, when the oxygen concentration value detected by the oxygen concentration detector 160 is less than the predetermined value (or a threshold value less than the predetermined value) by performing the inert gas purge mode, the state may be switched back to the dry air purge mode. By switching between the purge modes as described above, it is possible to adjust the oxygen concentration value in the first transfer chamber 12 so as not to exceed the predetermined value.

Further, the substrate processing apparatus 10 may be configured to be capable of performing the following purge modes in addition to or in combination with the purge modes (that is, the purge modes A, B and C) described above.

### Purge Mode D: Moisture Concentration Reduction Purge Mode

In order to reduce the oxygen concentration and the moisture concentration in the first transfer chamber 12, after performing a purge with the dry air in the dry air purge mode, a purge with the inert gas is performed by shifting to the inert gas purge mode. Procedures of such purge modes described above may also be collectively referred to as a “moisture concentration reduction purge mode”.

In the moisture concentration reduction purge mode, the moisture concentration in the first transfer chamber 12 is reduced by performing the dry air purge mode first. Thereafter, by performing the inert gas purge mode, the oxygen concentration in the first transfer chamber 12 is reduced (lowered). In addition, it is possible to maintain the moisture concentration (which was reduced in the dry air purge mode previously performed) at a low value.

A time (time duration) for removing the moisture remaining in the first transfer chamber 12 with the purge gas so as to reduce the moisture concentration to an allowable value may be longer than a time (time duration) for reducing the oxygen concentration in the first transfer chamber 12 to an allowable value. In such a case, by first using the dry air to sufficiently reduce the moisture concentration and then by using the inert gas, it is possible to reduce a usage amount of the inert gas. In addition, when an effect of the dry air in removing the moisture is greater than that of the inert gas in removing the moisture, it is also possible to reduce a time (time duration) for reducing the moisture concentration to the allowable value.

In addition, in the procedures of the moisture concentration reduction purge mode, the entire part of the dry air purge mode and at least a part of the inert gas purge mode (for example, until the oxygen concentration in the first transfer chamber 12 reaches the allowable value) can be performed before the substrates 100 stored in the pods 27-1 through 27-3 are transferred into the first transfer chamber 12. In addition, during the inert gas purge mode thereafter (for example, after the oxygen concentration and the moisture concentration in the first transfer chamber 12 reach the allowable values, respectively), the substrates 100 are transferred within the first transfer chamber 12.

Further, when the procedures of the moisture concentration reduction purge mode is performed, the rotational speed of the fan 171 in the dry air purge mode is higher than the rotational speed of the fan 171 in the inert gas purge mode. For example, the rotational speed of the fan 171 in the dry air purge mode is set to be equal to or higher than 80% and less than 90% and the rotational speed of the fan 171 in the inert gas purge mode is set to be equal to or higher than 60% and less than 80%.

By setting the rotational speed of the fan 171 in the dry air purge mode performed earlier to be higher than that of the fan 171 in the inert gas purge mode, it is possible to reduce the moisture concentration more quickly and uniformly in the first transfer chamber 12. Further, by setting the rotational speed of the fan 171 in the inert gas purge mode performed later to be lower than that of the fan 171 in the dry air purge mode performed earlier, it is possible to prevent (or suppress) the particles from spiraling upward in the first transfer chamber 12 due to an excessive flow velocity of the purge gas, and it is also possible to prevent (or suppress) the particles from adhering to the substrate 100 transferred in the first transfer chamber 12.

In the moisture concentration reduction purge mode, when the dry air is referred to as the “first purge gas” and the inert gas is referred to as the “second purge gas”, the dry air supplier may also be referred to as the “first purge gas supplier”, and the inert gas supplier may also be referred to as the “second purge gas supplier”. Further, the dry air purge mode may also be referred to as the “first purge mode”, and the inert gas purge mode may also be referred to as the “second purge mode”.

### Purge Mode E: Maintenance Purge Mode

When the operating personnel opens the maintenance door 190 to access the inside of the first transfer chamber 12, it is preferable to forcibly shift the purge mode to the dry air purge mode or the air purge mode regardless of which purge mode was in operation at the time of opening the maintenance door 190. Hereinafter, the purge mode following the forcible shift may also be collectively or individually referred to as a “maintenance purge mode”.

When the operating personnel opens the maintenance door 190 during the inert gas purge mode, the inner atmosphere of the first transfer chamber 12 becomes an inert gas atmosphere with a reduced oxygen concentration. Therefore, when the inert gas purge mode is continued even after the maintenance door 190 is opened, a safe operation of the operating personnel in the first transfer chamber 12 may be hindered due to the inert gas atmosphere with the reduced oxygen concentration.

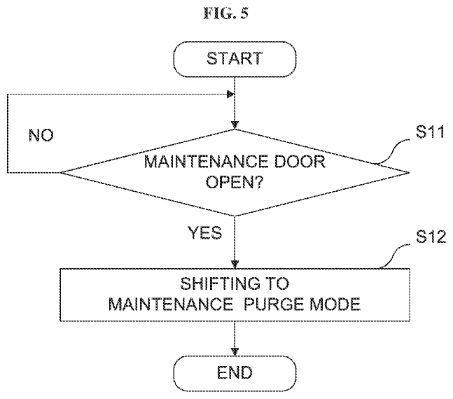

Therefore, according to the present embodiments as shown in FIG. 5, whether or not the maintenance door 190 is open is monitored (S11), and when the maintenance door 190 is opened, the purge mode is shifted to the dry air purge mode or the air purge mode serving as the maintenance purge mode regardless which purge mode was in operation at the time of opening the maintenance door 190 (S12). In the maintenance purge mode, from a viewpoint of suppressing an increase in the moisture concentration in the first transfer chamber 12 during the maintenance operation, it is preferable to perform the dry air purge mode.

While the maintenance door 190 is open (that is, during the maintenance purge mode), in parallel with prohibiting a shift to the inert gas purge mode, the inert gas supplier is controlled to stop a supply of the inert gas into the first transfer chamber 12. For example, the maintenance door 190 may be provided with a sensor (not shown) capable of detecting whether or not the maintenance door 190 is open. By acquiring a detection result of the sensor by the controller 121, it is possible to monitor whether or not the maintenance door 190 is opened.

Further, the fan 171 is controlled such that the rotational speed of the fan 171 when the maintenance door 190 is open (that is, in the maintenance purge mode) is higher than the rotational speed of the fan 171 when the maintenance door 190 is closed. By increasing the rotational speed of the fan 171 as described above, it is possible to prevent the particles or the like from entering the first transfer chamber 12, and it is also possible to further improve a safety of the operating personnel by quickly replacing the inner atmosphere of the first transfer chamber 12 with the dry air or the like when the first transfer chamber 12 is filled with the inert gas. Further, it is preferable that the rotational speed of the fan 171 when the maintenance door 190 is open (that is, in the maintenance purge mode) is higher than the rotational speed of the fan 171 in another purge mode. For example, the rotational speed of the fan 171 is set to be equal to or greater than 90% in the maintenance purge mode and equal to or greater than 60% and less than 90% in the inert gas purge mode before the purge mode is shifted.

In the maintenance purge mode, when the inert gas is referred to as the “first purge gas” and the dry air is referred to as the “second purge gas”, the inert gas supplier may also be referred to as the “first purge gas supplier”, and the dry air supplier may also be referred to as the “second purge gas supplier”. Further, the inert gas purge mode may also be referred to as the “first purge mode”, and the dry air purge mode may also be referred to as the “second purge mode”.

### Other Embodiments of Present Disclosure

The embodiments described above are described by way of an example in which the substrate processing apparatus 10 is an annealing apparatus. However, the substrate processing apparatus 10 according to the technique of the present disclosure is not limited to the annealing apparatus. That is, the technique of the present disclosure can be applied to a substrate processing apparatus in which the temperature of the substrate is elevated in the process chamber regardless of the contents of the substrate processing in the process chamber. As the substrate processing apparatus to which the technique of the present disclosure can be applied, for example, an apparatus capable of performing other processes such as a film-forming process, an etching process, a diffusion process, an oxidation process, a nitridation process and an ashing process may be used.

For example, the embodiments described above are described by way of an example in which the substrate 100 is used as a substrate to be transferred. However, the substrate to be transferred is not limited to the substrate 100. That is, the substrate to be transferred according to the technique of the present disclosure may include an object such as a photomask, a printed wiring board and a liquid crystal panel.

As described above, since the technique of the present disclosure can be implemented in various embodiments, the scope of the technique of the present disclosure is not limited to the embodiments described above. For example, the configuration of the substrate processing apparatus 10 (for example, the configurations of the process chambers 18A and 18B) described in the embodiments described above is merely a specific example, and the technique of the present disclosure (for example, the configuration of the substrate processing apparatus 10) may be modified in various ways without departing from the scope thereof.

According to some embodiments of the present disclosure, it is possible to easily adjust the inner atmosphere of the transfer chamber to a desired atmosphere when forming the air flow in the transfer chamber by using a plurality of different gases.

What is claimed is:

1. A substrate processing apparatus comprising:
a transfer chamber provided with a transfer space in which a substrate unloaded from a substrate storage container is transferred;
a first purge gas supplier through which a first purge gas is supplied into the transfer chamber;
a second purge gas supplier through which a second purge gas different from the first purge gas is supplied into the transfer chamber;
an exhauster through which an inner atmosphere of the transfer chamber is exhausted;
a circulation path connecting one end and the other end of the transfer space;
a fan provided on the circulation path or provided at an end portion of the circulation path and capable of circulating the inner atmosphere of the transfer chamber; and
a controller configured to be capable of controlling the fan such that a rotational speed of the fan varies between a first purge mode in which the first purge gas is supplied through the first purge gas supplier and a second purge mode in which the second purge gas is supplied through the second purge gas supplier.

2. The substrate processing apparatus of claim 1, wherein the first purge gas comprises normal air and the second purge gas comprises dry air whose moisture concentration is lower than that of the normal air, and
wherein the controller is further configured to be capable of controlling the fan such that the rotational speed of the fan in the second purge mode is higher than the rotational speed of the fan in the first purge mode.

3. The substrate processing apparatus of claim 1, wherein the first purge gas comprises normal air and the second purge gas comprises an inert gas, and
wherein the controller is further configured to be capable of controlling the fan such that the rotational speed of the fan in the second purge mode is higher than the rotational speed of the fan in the first purge mode.

4. The substrate processing apparatus of claim 1, wherein the first purge gas comprises dry air whose moisture concentration is lower than that of normal air and the second purge gas comprises an inert gas, and
wherein the controller is further configured to be capable of controlling the first purge gas supplier, the second purge gas supplier and the fan such that the second purge gas is supplied in the second purge mode after the first purge gas is supplied in the first purge mode.

5. The substrate processing apparatus of claim 4, wherein the controller is further configured to be capable of controlling the fan such that the rotational speed of the fan in the first purge mode is higher than the rotational speed of the fan in the second purge mode.

6. The substrate processing apparatus of claim 1, further comprising
an oxygen concentration sensor provided in at least one of the transfer chamber or an exhaust path constituting the exhauster,
wherein the second purge gas comprises an inert gas, and
wherein the controller is further configured to be capable of controlling a flow rate of the inert gas supplied into the transfer chamber through the second purge gas supplier based on a value detected by the oxygen concentration sensor in the second purge mode.

7. The substrate processing apparatus of claim 6, wherein the controller is further configured to be capable of controlling the flow rate of the inert gas supplied through the second purge gas supplier such that the value detected by the oxygen concentration sensor in the second purge mode becomes a predetermined value.

8. The substrate processing apparatus of claim 6, wherein the controller is further configured to be capable of controlling the rotational speed of the fan in accordance with the flow rate of the inert gas in the second purge mode.

9. The substrate processing apparatus of claim 6, wherein the controller is further configured to be capable of controlling the rotational speed of the fan based on the value detected by the oxygen concentration sensor in the second purge mode.

10. The substrate processing apparatus of claim 1, further comprising
a moisture concentration sensor provided in at least one of the transfer chamber or an exhaust path constituting the exhauster,
wherein the first purge gas comprises normal air and the second purge gas comprises a dry gas whose moisture concentration is lower than that of the normal air, and
wherein the controller is further configured to be capable of controlling a flow rate of the dry gas supplied into the transfer chamber through the second purge gas supplier based on a value detected by the moisture concentration sensor in the second purge mode.

11. The substrate processing apparatus of claim 10, wherein the controller is further configured to be capable of controlling the flow rate of the dry gas supplied through the second purge gas supplier such that the value detected by the moisture concentration sensor in the second purge mode becomes a predetermined value.

12. The substrate processing apparatus of claim 10, wherein the controller is further configured to be capable of controlling the rotational speed of the fan in accordance with the flow rate of the dry gas in the second purge mode.

13. The substrate processing apparatus of claim 10, wherein the controller is further configured to be capable of controlling the rotational speed of the fan based on the value detected by the moisture concentration sensor in the second purge mode.

14. The substrate processing apparatus of claim 1, further comprising
an oxygen concentration sensor provided in at least one of the transfer chamber or an exhaust path constituting the exhauster,
wherein the first purge gas comprises an inert gas and the second purge gas comprises dry air whose moisture concentration is lower than that of normal air, and
wherein the controller is further configured to be capable of controlling the first purge gas supplier and the second purge gas supplier such that the inert gas is supplied into the transfer chamber by switching to the first purge mode when a value detected by the oxygen concentration sensor exceeds a predetermined value in the second purge mode.

15. The substrate processing apparatus of claim 1, wherein further comprising
a door provided at an opening through which an inside of the transfer chamber communicates with an outside of the transfer chamber,
wherein the first purge gas comprises an inert gas and the second purge gas comprises dry air whose moisture concentration is lower than that of normal air, and
wherein the controller is further configured to be capable of controlling the second purge gas supplier such that the dry air is supplied into the transfer chamber in the second purge mode when the door is open.

16. The substrate processing apparatus of claim 15, wherein the controller is further configured to be capable of controlling the first purge gas supplier such that a shift to the first purge mode is prohibited and a supply of the inert gas into the transfer chamber is stopped when the door is open.

17. The substrate processing apparatus of claim 15, wherein the controller is further configured to be capable of controlling the fan such that the rotational speed of the fan when the door is open is higher than the rotational speed of the fan when the door is closed.

18. A method of manufacturing a semiconductor device, comprising:
(a) transferring a substrate unloaded from a substrate storage container within a transfer chamber; and
(b) circulating an inner atmosphere of the transfer chamber by a fan provided in the transfer chamber while supplying a first purge gas or a second purge gas different from the first purge gas into the transfer chamber and exhausting the inner atmosphere of the transfer chamber,
wherein, in (b), the fan is controlled such that a rotational speed of the fan varies between a first purge mode in which the first purge gas is supplied and a second purge mode in which the second purge gas is supplied.

19. A non-transitory computer-readable recording medium storing a program that causes, by a computer, a substrate processing apparatus to perform:
(a) transferring a substrate unloaded from a substrate storage container within a transfer chamber; and
(b) circulating an inner atmosphere of the transfer chamber by a fan provided in the transfer chamber while supplying a first purge gas or a second purge gas different from the first purge gas into the transfer chamber and exhausting the inner atmosphere of the transfer chamber,
wherein, in (b), the fan is controlled such that a rotational speed of the fan varies between a first purge mode in which the first purge gas is supplied and a second purge mode in which the second purge gas is supplied.
